(19) United States
(12) Patent Application Publication
(10) Pub. No.: US 2014/0357080 A1
(43) Pub. Date: Dec. 4, 2014

(54) METHOD FOR PREFERENTIAL SHRINK AND BIAS CONTROL IN CONTACT SHRINK ETCH

(71) Applicant: TOKYO ELECTRON LIMITED, Tokyo (JP)

(72) Inventors: Anthony D. LISI, Hopewell Junction, NY (US); Hongyun COTTLE, Schenectady, NY (US)

(73) Assignee: TOKYO ELECTRON LIMITED, Tokyo (JP)

(21) Appl. No.: 14/294,253

(22) Filed: Jun. 3, 2014

Related U.S. Application Data
(60) Provisional application No. 61/830,870, filed on Jun. 4, 2013.

(51) Int. Cl. H01L 21/3065; H01L 21/768; H01L 21/033

(52) U.S. Cl. CPC H01L 21/3065; H01L 21/0332; H01L 21/0338; H01L 21/76877
USPC 438/675; 438/717

(57) ABSTRACT

A method for providing a shrink etch in which the features to be etched in a target layer have major and minor dimensions with the major dimension larger than the minor dimension. In the shrink etch of a mask, the dimensions are reduced from that of a patterned resist of the mask, however, with conventional techniques, the shrink etch undesirably shrinks by a greater amount in the major axis dimension. By treating the resist prior to the shrink etch, the shrinking is made more uniform, and if desired in accordance with processes herein, the amount of shrinkage in the major axis can be the same as or less than that in the minor axis direction.

### CROSS REFERENCE TO RELATED APPLICATIONS

This application claims priority to provisional application 61/830,870, filed Jun. 4, 2013, the entirety of which is incorporated herein by reference.

### FIELD OF THE INVENTION

The invention relates to etching, and particularly to a method for improving the control of the shrink in a shrink etch process.

### BACKGROUND OF THE INVENTION

In fabricating semiconductor devices, it is difficult to achieve sufficiently small feature sizes in dense patterns, particularly while also maintaining desired feature shapes and dimensions of such shapes.

In accordance with one known way to provide decreased feature sizes, a shrink etch process is used. With this process, a patterned photoresist is used to etch portions of a mask to form a patterned mask, with the mask disposed above a target layer which is ultimately to be etched. When the mask layer is etched, the etch is tapered, so that the pattern of the etched mask is smaller or shrinks relative to the pattern in the photoresist. As a result, after the mask is etched to form a patterned mask, the patterned mask provides a pattern through which the target layer can be etched with feature sizes smaller than that of the initial patterned photoresist.

However, problems arise with such a shrink etch process in that the shrinking is not uniform. The problem with non-uniform shrinking is particularly apparent with features having a shape which is not axially symmetric, for example, features having different X and Y dimensions, such as oval, elliptical, slit or rectangular features. With such features, the shrinkage in the larger dimension, the Y dimension, is greater than in the X direction. Further, if this is attempted to be accommodated for by increasing the Y dimension in the original patterned resist, this can risk problems associated with limitations on the photolithographic process used to form the patterned resist, such as breaching in the Y direction. Modifying the original photoresist pattern can also sacrifice control of the feature size in the X direction. These problems or challenges can be particularly apparent with large numbers of densely packed features.

Where the target layer to be etched is etched to form a trench that is later filled with metal to form a contact layer (contact etch), control over the dimensions in both the X and Y directions is critical, and therefore, shrinking which is non-uniform or not sufficiently controlled is problematic.

### SUMMARY OF THE INVENTION

In accordance with the invention, the inventors have recognized methods for improved control of a shrink etch. Preferably, a shrink etch is conducted so that it is uniform, so that a 1:1 shrink ratio of ΔX to ΔY is achieved, and the shrinkage is controlled, uniform and predictable. Further, in accordance with the present invention, it is possible to achieve shrinkage control so that the shrinkage in the X direction can actually be larger than in the Y direction so that the shrink ratio can be 1:≦1 (in terms of ΔX shrinkage to ΔY shrinkage). By contrast, with conventional shrink etch techniques, where the X dimension is smaller than the Y dimension, the shrinkage of ΔX to ΔY is 1:>1.

In accordance with the present invention, the resist layer is modified before patterning of the remainder of the mask layer. By way of example, a conformal or uniform hydrocarbon deposition step can be used before patterning or etching of a silicon anti-reflective coating (SiARC). In accordance with the present invention, this modification can achieve 1:≦1 X to Y shrink ratios that were not achieved with conventional fluorocarbon etch based shrink processes. After the conformal hydrocarbon deposition, a SiARC (or other ARC) definition step can proceed anisotropically to provide a tapered etch. Thereafter, the remainder of the mask can be etched. The etched or patterned mask can subsequently be used in etching the target layer. According to an example of the invention, a SiARC layer is used beneath the resist, however, other types of ARC layers could be used, for example a TiARC, or a fully organic anti-reflective coating or BARC.

CH4 processing can be used to process the photoresist material. However, CH4 is not always present or available in all etching tools. With the invention, processing can proceed without using CH4, for example, using a mixture of CH3F and H2. This provides results similar to the use of CH4. In addition, the photoresist processing can also be used with direct current (DC) power applied to the plasma. The added application of DC power can provide ballistic electrons to enhance the plasma density for the deposition, and can also serve to harden the photoresist. For example, a negative DC bias power can be superposed upon an upper electrode in preforming the deposition prior to the SiARC patterning.

Various expedients can be used to adjust the deposition and thus the shrink control, for example, in varying the deposition time, in varying the gas chemistry (or gas mixture ratios), varying pressure, and/or varying the negative DC bias applied (in terms of the voltage and/or power). As discussed herein, additional optional modifications can also be used, for example, in etching the SiARC layer in a two-step process, and/or in etching an organic planarization layer beneath the SiARC for additional control over the resulting shrink/shrink ratio. As a result, the shrink ratio can be varied or adjusted. In general, a ratio of 1:1 is preferred, however, there can be situations in which a greater shrink in the X direction (or the smaller dimension) might be desired, and in accordance with the present invention, a greater shrink in the X direction as compared with the Y direction can be achieved. By contrast, with conventional techniques, shrinkage in the larger direction or Y direction results.

The invention will be further appreciated with reference to the detailed description herein, particularly with reference to the accompanying drawings. Although, various features and advantages are described in combination herein, it is to be understood that certain features or advantages could be utilized without using others. Accordingly, it is to be understood that, in practicing the invention, subsets of features described herein could be used, or alternative similar features could be utilized, without utilizing other features. In addition, it is to be understood that variations are possible, for example, in utilizing process steps preformed in a different order, with additional steps performed, or with different materials utilized in different layers of the substrate being processed with variations also used in the process chemistries.

### BRIEF DESCRIPTION OF THE DRAWINGS

FIG. 1 is a plan view of examples of etched features having different X and Y dimensions;

FIG. 2 is a side cross-section of a substrate having a patterned resist, prior to patterning of the remainder of the mask;

FIG. 3 is a side cross-section after patterning of the mask and etching of a target layer;

FIG. 4 is a flow chart of the present method; and

FIG. 5 illustrates a comparison with SEM images of advantageous results achieved with the invention and a comparative example.

### DETAILED DESCRIPTION OF THE PREFERRED EMBODIMENTS

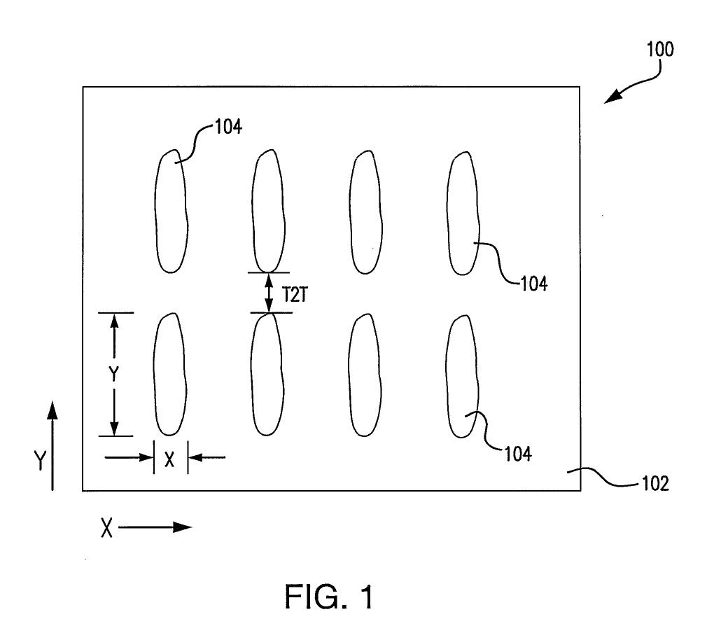

Referring to FIG. 1, a plan view is illustrated (in a direction perpendicular to the surface of the substrate, looking down) of a layer 102 of a substrate 100 to which the present invention is applicable. FIG. 1 illustrates the substrate after etching features 104 into a target layer 102, with the features having a Y dimension or major axis dimension larger than another X dimension or minor axis dimension. For example, such features 104 can be utilized for forming contacts, in which after the features 104 are etched, they are filled with a conductive metal (e.g., tungsten) so that the layer 102 becomes a contact layer. As will be discussed later, when etching such features, in order to make the features of desired small dimensions, a shrink etch process is utilized, so that the critical or desired dimensions of the resulting etched target layer are smaller than that of the resist utilized in starting the etch processes. However, when performing the shrink etch, the shrinkage of the dimensions is not uniform in the X and Y directions with conventional techniques. With conventional techniques, greater shrinkage in the Y direction occurs due to the larger feature sizes or dimensions in the Y direction. As a result, if the Y dimension is smaller, the tip to tip spacing (identified in FIG. 1 as T2T) becomes larger, which is undesirable, as connections can be required to be made along the Y direction or established in the Y direction. It is also important to maintain sufficient spacing between adjacent features 104 in the X direction, to ensure sufficient isolation between adjacent features 104.

Although the features 104 are illustrated as elongated ovals, the invention can be advantageously utilized for various feature shapes which are not axially symmetric, such as ellipses or shorter ovals, rectangular features, slits, curved or bent shapes, etc., in which one dimension or a major axis dimension is larger than a second dimension or minor axis dimension.

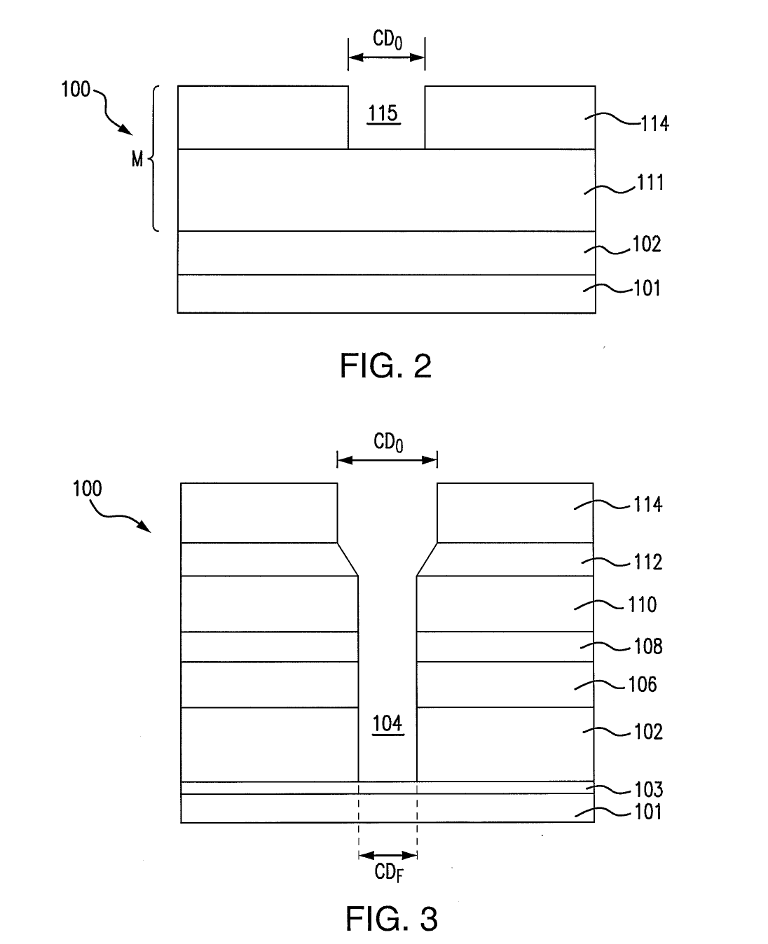

Referring to FIG. 2, a general representation of a substrate 100 is provided prior to processing in accordance with the invention. In the illustrated arrangement, a substrate base 101, such as a silicon wafer, is provided, above which is a target layer 102 which is desired to ultimately be etched. It is to be understood that multiple layers can be provided between the target layer 102 and the substrate 101. A mask M is provided above the target layer 102. The mask M includes a resist (photoresist) layer 114 as well as additional layers represented collectively at 111 in FIG. 2, examples of which will be discussed in further detail hereinafter.

The resist layer 114 includes an opening 115 formed or patterned with a photolithographic process, and having an initial critical dimension CD0. Due to limitations in the initial patterning of the resist, the initial critical dimensions of the resist 114 are larger than the desired final critical dimensions of the features to be etched in the target layer 102. Accordingly, a shrink etch process is used, by which, in opening of the remaining layers of the mask, the feature size is reduced or shrinked. However, with conventional techniques as discussed earlier, the shrinking is not uniform, particularly where the features have different dimensions in X and Y directions, with the Y dimension (or larger dimension) undesirably shrinking more than the X dimension (or smaller dimension). Accordingly, prior to opening of the additional mask layers 111, in accordance with the present invention, an additional deposition or processing step is provided for the resist layer 114. Additional modifications can also be utilized in opening of the additional mask layers 111 as discussed further herein.

In accordance with an example of the invention, deposition with a hydrocarbon gas is used before opening of the remaining mask layers 111. In accordance with the invention, a 1:1 ΔX to ΔY shrink ratio can be achieved, and further, if desired a larger shrinkage in the X direction can also be achieved. In processing or modifying the resist 114, a CH4 gas can be used, however, CH4 is not always available. Thus, in accordance with one of the features of an example of the invention, a CₓH_{y}F_{z} gas (in which, x, y, and z are greater than 0) is used in combination with H2. By way of example and not to be construed as limiting, a CH3F and H2 mixture can be used at a 1:7 ratio. The amount/ratio of H2 to CₓH_{y}F_{z} can be varied, and preferably a flow rate ratio of H2 to CₓH_{y}F_{z} is in a range of 4:1 to 10:1.

The target layer 102 which is ultimately to be etched can be, for example, a contact layer in which the etched openings (104) are subsequently filled with a conductive material used to interconnect features or devices formed adjacent (above or below) the target layer. By way of example, and not to be construed as liming, the layer 102 can provide a contact layer in which the filled openings 104 are used to create contacts with a FinFET (Fin Field Effect Transistor), in which the filled openings in the Y direction are aligned with Fins spaced in the Y direction. However, in such an arrangement, if the feature dimension in the X direction is too wide, or if there is insufficient spacing in the X direction between adjacent features 104, a contact fill with a conductive material can cause a short circuit. In addition, if there is an insufficient dimension in the Y direction (which is also seen as an excessively large tip to tip or T2T spacing between adjacent features 104 in the Y direction), the fill with a conductive material can fail to make contact.

Referring to FIG. 3, an example of an etched profile is illustrated, and additional details of an example of the invention will be described. As illustrated in FIG. 3, the initial critical dimensions CD0 of the resist layer 114 are larger than the desired final critical dimensions CDF in the target layer 102 with the layer 102, for example, a contact layer formed of a dielectric material. The layer 102 can be, for example, an oxide layer. Beneath the layer 102 can be, for example, a nitride layer, such as a SiN layer or layer used as an etch stop underneath the layer 102. The substrate or substrate base 101 is illustrated beneath the layer 103, however, it is to be understood that multiple layers can be provided between the layer 103 and the substrate base 101.

To obtain the final desired critical dimensions CDF which are smaller than the initial resist opening dimensions CD0, a shrink etch is utilized in which a portion of the etching through the mask layer M shrinks or is tapered with an anisotropic etch. In the illustrated arrangement, beneath the resist layer 114, an ARC (anti-reflective coating) layer 112 is provided, and particularly a SiARC layer, which is etched to have a tapered profile to form the shrink etch. According to an example of the invention, a SiARC layer is used beneath the resist, however, other types of ARC layers could be used, for example a TiARC, or a fully organic anti-reflective coating or BARC. The remaining layers can then be opened or etched substantially vertically to complete opening of the mask M. Thereafter, the mask is used to etch the features 104 in the target layer 102, for example, so that the features 104 can then be filled to provide the layer 102 as a contact layer. It is to be understood that various materials and different layer structures could be utilized for the mask M. In the illustrated example, beneath the SiARC layer 112, an organic planarization layer or OPL 110 is provided, beneath which a SiON layer 108 is provided. A layer 106 which can be, for example, an amorphous carbon layer, is provided beneath layer 108 and above the target layer 102. The mask M can have a smaller or larger number of layers, and different materials could be utilized.

As discussed earlier, in order to avoid problems that can occur with an undesirable shrink ratio (in which there is undesirable greater shrinking in the Y direction compared to the X direction), before opening of the SiARC layer 112, the substrate having the opened resist layer 114 is processed, for example, with a deposition process using a hydrocarbon gas. In accordance with an example, a CₓH_{y}F_{z} gas and H2 gas mixture is used prior to opening of remaining portions of the mask M. A ratio of H2 to CₓH_{y}F_{z} flow rates is preferably in a range of 4:1 to 10:1, for example 7:1. By way of example, gases used in combination with additional hydrogen can include CH3F, CH2F2, or CHF3. The hydrogen will extract or getter fluorine so that, for example, the formation or sticking of deposits is reduced. Typical etching progresses with a fluorocarbon gas which can produce deposits such as PTFE (polytetrafluoroethylene), and because the collection angle is wider in larger feature dimensions, the Y dimension can shrink by a greater amount than in the X direction. This effect is avoided or minimized in accordance with the invention. CH4 can also be used in processing the resist layer, however, CH4 is not always available. A CₓH_{y}F_{z} and H2 gas mixture will mimic CH4 in the formation of methyl radicals. After the resist is treated with a deposition process, etching through the remaining layers of the mask M can proceed. Due to the resist treatment, fluorine based deposits (which can deposit in larger amounts in the Y direction and thus cause the undesired excess shrinking in the Y direction) are reduced as the etching or opening of the remainder of the mask M proceeds.

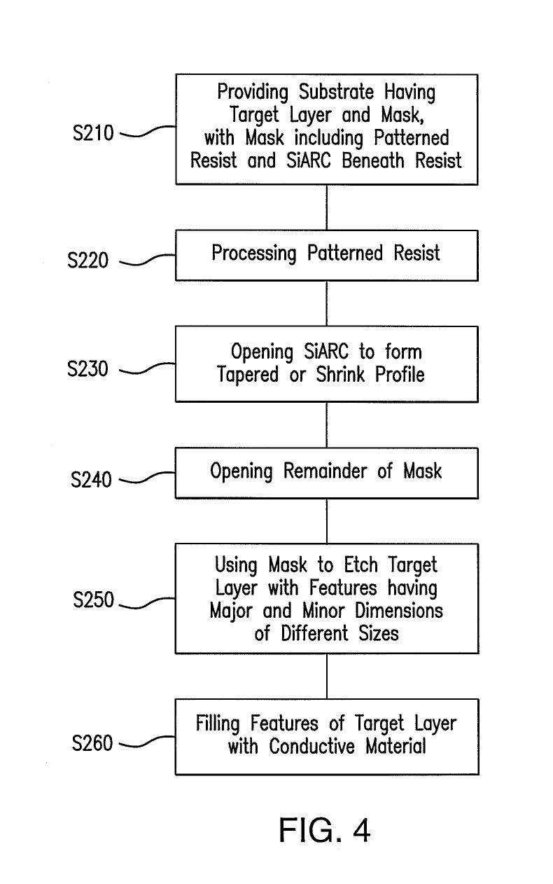

Referring to FIG. 4, a flowchart representing an example of a process of the invention is illustrated.

Initially, in step S210, a substrate is provided having a target layer and a mask in the form of plural mask layers. The mask layer includes at least a soft mask such as a patterned photoresist layer, and at least one underlying layer which is utilized to provide the tapered or shrink etch profile, but which is not yet opened or patterned (FIG. 2). For example, in the embodiment discussed earlier, a patterned photoresist layer is provided above a SiARC or other ARC layer. Features in the photoresist have different dimensions in the X and Y directions to provide shapes desired to be formed in the target layer, but with the features of the resist pattern larger than the desired final critical dimensions. The patterned photoresist is then treated in step S220, for example, with a deposition process using a hydrocarbon gas, e.g., using a mixture of CₓH_{y}F_{z} and H2.

In step S230, the layer under the photoresist is then opened or etched to form a tapered or shrink profile, in opening of the SiARC layer in the present example.

In accordance with an additional optional modification, the opening of the SiARC layer can be performed in two steps as discussed further hereinafter.

Thereafter, the remainder of the mask is opened in step S240. Conventional processes can be used for opening the remainder of the mask layers S240. However, in accordance with an additional optional modification, in etching through, for example, an OPL layer, an oxidative etch (for example using 02 and Argon) can be utilized for at least part of the OPL etch so that a larger collection angle for etchant radicals enlarges the dimension in the Y direction relative to (or preferential to) the X direction.

Thereafter, in step S250, the mask is used to etch the target layer. The present invention is particularly advantageous for etching features in a target layer having major and minor dimensions (X and Y) of different sizes, because the present invention can achieve shrinkage which is substantially the same (or 1:1 ratio) in the major dimension or Y direction as compared with the minor dimension or X direction. In fact, if desired, the invention can achieve shrinkage in the X direction which is larger than that in the Y direction, so that a 1:≦1 ΔX to ΔY shrink is achieved. By contrast, with conventional techniques, undesirable greater shrinkage in the Y direction occurs as compared with the X direction.

After the features are etched in the target layer, remaining portions of the mask can be removed in an ashing process. The etched features of the target layer can subsequently be filled in step S260 with a conductive material or conductive metal (e.g., tungsten), so that the target layer can form a contact or connecting layer in a substrate, e.g., a semiconductor substrate.

By way of example, processing can be performed in a process chamber including upper and lower electrodes with a process space therebetween, and with the substrate positioned on the lower electrode or electrostatic chuck (ESC). Power at a frequency of 60 MHz can be applied to the upper electrode and power at a frequency of 13.56 MHz can be applied to the lower electrode. Process gases can be supplied by way of a showerhead arrangement, for example. In addition, according to a preferred example, a negative DC voltage power is also applied to the upper electrode during the deposition processing of the resist (S220). This can enhance the plasma density for the deposition and can also provide additional curing or hardening of the resist. Although the DC power could also be applied during other steps, it is presently preferred to discontinue the DC power after the resist processing, so that the SiARC (or other ARC) etching proceeds without application of the DC power. It is to be understood that various equipment types or modifications can be used. For example, frequencies other than 60 MHz and 13.56 MHz could be used, and processing could proceed with a single frequency or more than two frequencies.

Examples of process conditions will now be provided, by way of a non-limiting example. It is to be understood that different processing equipment configurations can be utilized, and process conditions can be varied, as can be process gas chemistries. Accordingly, it is to be understood, the following conditions are provided only as examples.

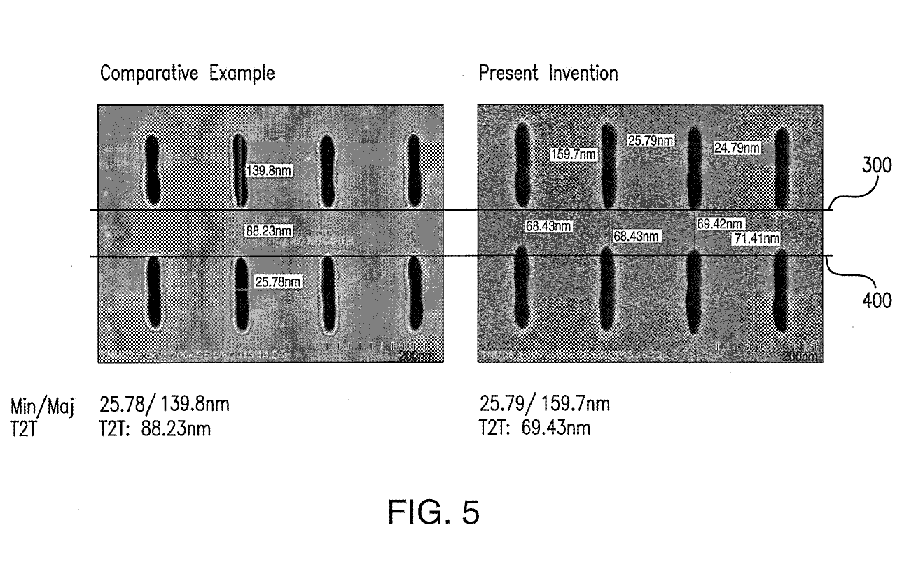

Referring to FIG. 5, advantages achieved in accordance with the present invention can be appreciated. FIG. 5 illustrates the features formed in the target or dielectric layer (102) in which the same initial patterned photoresists were used. The target feature length was 160 nm, and the target tip to tip (T2T) spacing for the feature etched in the target layer was 68 nm. In FIG. 5, the left SEM image shows processing and the results of shrinking with a comparative example in which the resist layer was not processed prior to the SiARC etch, whereas the right image illustrates results achieved in accordance with an example of the present invention. The processes were controlled to achieve a required or target X dimension, and the results therefore have a common X dimension. Thus, the results demonstrate the ability of the invention to achieve the desired Y and T2T dimensions for a given X dimension, whereas with the comparative example for the same photoresist and achieving the same given X dimension, excess shrinkage in the Y direction resulted, also causing the T2T dimension to be unsatisfactory. The lines 300, 400 provide an extension of the tips from the left image through the right image, to further show the improved results and the reduction in the T2T spacing using a hydrocarbon deposition step prior to ARC opening. With the comparative example, the T2T spacing was 88.23 nm, whereas with the present invention a T2T spacing of 69.43 nm was achieved (very close to the target). In addition, the X dimension in the feature etched in the dielectric layer was 25.78 nm and the Y dimension 139.8 nm for the comparative example, whereas with the present invention, the X dimension was 25.79 and the Y dimension 159.7 nm (very close to the target). Accordingly, for a given X dimension, the shrinkage amount in the Y dimension was significantly reduced, and dimensions very close to the targets were achieved in terms of the feature length and the T2T spacing. For the comparative example, the process conditions were as follows: SiARC etch: 30 mT pressure, 500 W/350 W, −500 volts DC, 250CF4/10C4F8/200Ar, 25 seconds process time; OPL etch: 50 mT, 1200 W/125 W, 400H2/200N2, 190 s, 8/8C; mask finish etch: 150 mT, 1500 W/250 W, 200CF4, 20 s, 8/8C. For the example of the invention, the photoresist was treated using a hydrocarbon gas and hydrogen, and then the SiARC etch was performed, with the following conditions: photoresist treatment: 40 mT, 500 W/150 W, −500 DC, 44CH3F/308H2, RDC=50, 5 s process time; SiARC etch: 15 mT, 0/800 W, no DC in SiARC etch, 250CF4/13C4F8/200Ar, 20 s; OPL etch: 50 mT, 1200/125 W, 400H2/200N2, 190 s, 8/8C; mask finish etch: 150 mT, 1500 W/250 W, 200CF4, 20 s, 8/8C. In the above, all gas flow values are in sccm, and the two power amounts separated by a slash for each step respectively indicate the amount of 60 MHz and 13.56 MHz power applied. The DC power was applied to an upper electrode, and where DC power is not indicated for a given step, it was not applied. The temperatures refer to the electrostatic chuck (ESC) temperature.

Thus, the results demonstrate that the problem with excess shrinkage in the Y direction can be eliminated, and an improved shrink ratio can be achieved. With the present invention, a shrink ratio of 1:1 X to Y shrink amount can be achieved, and further, a lower amount of shrinkage in the Y direction can be achieved than in the X direction if desired.

In accordance with a further example, as mentioned earlier, a two step ARC or SiARC etch process can be used. In processing the photoresist in a deposition process, a 40 mTorr pressure was utilized, in an etching chamber having upper and lower electrodes, with 60 MHz at 500 W applied to the upper electrode and 13.56 MHz at 150 W applied to the lower electrode, and further with a negative DC power at 500 volts applied or superposed onto the upper electrode for processing of the photoresist. The gas composition included 308 sccm H2 and 44 sccm CH3F. In addition, the temperature of the wafer support or electrostatic chuck (ESC, or lower electrode) was maintained at 3° C., and processing proceeded for 5 seconds.

Thereafter, a first SiARC opening step processing proceeded at 30 mTorr, with 350 W applied to the upper electrode and 450 W applied to the lower electrode (frequencies remaining the same throughout), with the DC power discontinued after the photoresist processing. In the first SiARC processing step, the gas chemistry included 40 sccm CH3F, 350 sccm H2, and 120 sccm N2, with the ESC temperature maintained at 3° C., and processing proceeded for 14 seconds. Thereafter, in a second SiARC opening step, at 30 mTorr, the power applied to the upper and lower electrodes was 200 W and 450 W, respectively (same frequencies of 60 MHz and 13.56 MHz throughout), with 250 sccm CF4 and 125 CHF3, and with the ESC at 3° C., and processing continuing for 17 seconds to complete opening of the SiARC layer. Thereafter, in opening the OPL, a process pressure of 50 mTorr was used, with 1200 W and 125 W power applied respectively to the upper and lower electrodes, and the process chemistry of 400 sccm H2 and 200 sccm N2, and with the ESC temperature at 8° C., with processing proceeding for 160 seconds. The remainder of the mask was then opened and the target layer dielectric or contact layer was then etched using conventional techniques. The results demonstrated the ability to further control the shrinkage in X and Y dimensions using a two-step SiARC etch, so that the shrink amount in the Y dimension can be the same as or less than that in the X direction.

In the above example, a two-step ARC or SiARC opening or etching is used with different process chemistries and different etch rates (with the second having a faster etch rate than the first in the above example). In the above example, the two steps also provide better pattern fidelity (less wiggling along the feature shape) during etching with a first step, and the second step provides an over-etch and ensures etching of features across the wafer/substrate (ensuring different locations, types and/or densities of features are fully etched). The two-step ARC or SiARC also allows one of the steps to be performed with a leaner (less polymer) chemistry. The two-step SiARC etch can further tailor the X and Y shrinkage or tapering, and can further be modified according to duration, chemistry, pressure, power, thus providing additional control modification options. It is to be understood that a single ARC or SiARC etch could also be used as discussed earlier, and where two step ARC or SiARC processing is used, the order of the two-steps could be reversed, or more than two steps could be used. As used herein, two-step processing means two or more processing steps can be used (in other words, the reference to a two-step process does not exclude the use of additional steps). In addition, as a further optional modification as noted earlier, during a portion of the OPL etch, an oxidation etch could be used (e.g., using O2 and Argon) for additional tailoring or control of the process.

It is to be understood that the process conditions can be varied to suit different feature types/shapes and dimensions, and different materials, including for example varying of the process chemistry used in deposition with respect to the photoresist layer, in opening the SiARC and/or the OPL. In addition, variations can be made to the pressures used, power applied, the amount of time of the process steps, gas chemistries or gas ratios. Accordingly, it is to be understood that variations are possible in light of the teachings of the invention.

As will be appreciated, the present invention provides advantageous results as compared with conventional processes. The present invention is particularly advantageous where a shrink etching is performed, for example, to etch features in a contact layer which is subsequently filled with a conductor. The invention is particularly advantageous in being able to control shrinkage amounts of features which have different dimensions, with a major dimension or Y axis dimension larger than that of a minor dimension or X axis dimension. Because variations are possible, it is to be understood that the description herein should not be construed as limiting beyond the language of the appended claims.

1. A method of etching a target layer comprising:
providing a substrate having the target layer thereon and a mask above the target layer, wherein a top portion of the mask is patterned with features having first and second dimensions in which the first dimension is larger than the second dimension, and wherein portions of the mask below the top portion are not patterned such that the mask is a partially opened mask;
performing a plasma deposition on the partially opened mask with a hydrocarbon gas;
after the plasma deposition, etching through remaining portions of the mask layer to form an open mask, and wherein during at least a portion of the etching through remaining portions of the mask a taper etch profile is formed such that openings at a bottom of the open mask have a first mask bottom dimension and a second mask bottom dimension wherein the first mask bottom dimension is larger than the second mask bottom dimension, and wherein at least one of: (a) the first mask bottom dimension is smaller than the first dimension, or (b) the second mask bottom dimension is smaller than the second dimension; and
etching the target layer through the open mask.

2. A method according to claim 1, wherein the top portion of the mask comprises a resist layer, and wherein the remaining portions of the mask comprise an ARC layer, and wherein the taper etch profile is formed in the ARC layer.

3. A method according to claim 2, wherein etching of the ARC layer is performed in two steps at two different etch rates and two different plasma chemistries.

4. A method according to claim 3, wherein the two steps are performed in a process chamber, wherein the two steps include a first step followed by a second step, and wherein a larger amount of hydrogen is fed to the process chamber during one of the first and second steps than during the other of the first and second steps.

5. A method according to claim 4, wherein the process chamber comprises an upper electrode and wherein the method further comprises, during performing the plasma deposition on the partially opened mask, applying a negative voltage direct current power to the upper electrode.

6. A method according to claim 5, wherein after etching of the target layer etched features in the target layer have a first target layer dimension and a second target layer dimension, wherein the first target layer dimension is larger than the second target layer dimension, and wherein a first shrink amount is said first dimension minus said first target layer dimension, and a second shrink amount is said second dimension minus said second target layer dimension, and further wherein a ratio of said second shrink amount to said first shrink amount is 1:≦1.

7. A method according to claim 6, wherein during the plasma deposition, CₓH_{y}F_{z} and H2 are supplied to the process chamber.

8. A method according to claim 7, wherein a flow rate ratio of H2 to CₓH_{y}F_{z} is from 4:1 to 10:1.

9. A method according to claim 1, wherein after etching of the target layer etched features in the target layer have a first target layer dimension and a second target layer dimension wherein the first target layer dimension is larger than the second target dimension, and wherein a first shrink amount is said first dimension minus said first target layer dimension, and a second shrink amount is said second dimension minus said second target layer dimension, and further wherein a ratio of said second shrink amount to said first shrink amount is 1:≦1.

10. A method according to claim 9, further including filling etched features in the target layer with a conductive metal.

11. A method according to claim 1, wherein the top portion of the mask comprises a patterned resist layer, and wherein during the plasma deposition H2 and CₓH_{y}F_{z} are supplied at a flow rate ratio of H2 to CₓH_{y}F_{z} of from 4:1 to 10:1, and further wherein the remaining portions of the mask comprise a SiARC layer, and wherein the taper etch profile is formed in the SiARC layer.

12. A process comprising:
providing a substrate having a target layer thereon;
providing a mask above the target layer, wherein the mask comprises a patterned resist layer and an ARC layer beneath the patterned resist layer, and wherein portions of the mask beneath the resist layer are not opened such that the mask is partially patterned mask and the target layer is not exposed, wherein the patterned resist includes features each having a first dimension and a second dimension, wherein the first dimension is larger than the second dimension;
processing the partially patterned mask with a hydrocarbon gas;
etching through portions of the mask beneath the resist layer to form a patterned mask and to expose the target layer, wherein during etching through portions of the mask beneath the resist layer an etch profile is formed and at least part of the etch profile includes a tapered profile such that openings at a bottom of the patterned mask have a first mask bottom dimension and a second mask bottom dimension, wherein the first mask bottom dimension is larger than the second mask bottom dimension, and wherein at least one of: (a) the first mask bottom dimension is smaller than the first dimension, or (b) the second mask bottom dimension is smaller than the second dimension; and
etching the target layer through the patterned mask;
wherein after etching through the target layer etched features in the target layer have a first target layer dimension and a second target layer dimension, wherein the first target layer dimension is larger than the second target layer dimension, and wherein a first shrink amount is said first dimension minus said first target layer dimension, and a second shrink amount is said second dimension minus said second target layer dimension, and further wherein a ratio of said second shrink amount to said first shrink amount is 1:≦1.

13. A process according to claim 12, wherein the ARC layer is a SiARC layer, wherein the tapered profile is formed in the SiARC layer, and wherein during processing of the partially patterned mask with a hydrocarbon gas, H2 and CₓH_{y}F_{z} are supplied at a flow rate ratio of H2 to CₓH_{y}F_{z} of from 4:1 to 10:1.

14. A method according to claim 13, wherein etching of the SiARC layer is performed in two steps at two different etch rates and two different plasma chemistries.

15. A method according to claim 14, wherein the two steps include a first step followed by a second step, and wherein a larger amount of hydrogen is fed to a process chamber in which processing is performed during one of the first and second steps than during the other of the first and second steps.

16. A method according to claim 15, wherein the mask further includes an organic layer disposed beneath the SiARC layer, and further wherein during etching through portions of the mask beneath the resist layer the organic layer is etched, and further wherein during etching of at least a portion of the organic layer an oxidative etch is performed.

17. A method according to claim 16, wherein during processing of the partially patterned mask with a hydrocarbon gas, a plasma deposition process is performed and further wherein during said plasma deposition process a direct current power is applied, and further wherein the direct current power is a negative direct current power applied to an upper electrode.

18. A process comprising:
providing a substrate having a target layer thereon;
providing a mask above the target layer, wherein the mask comprises a patterned resist layer and a SiARC layer beneath the patterned resist layer, and wherein portions of the mask beneath the resist layer are not opened such that the mask is partially patterned mask and the target layer is not exposed, wherein the patterned resist includes features each having a first dimension and a second dimension, wherein the first dimension is larger than the second dimension;
processing the partially patterned mask with a hydrocarbon gas;
etching through portions of the mask beneath the resist layer to form a patterned mask and expose the target layer, wherein during etching through portions of the mask beneath the resist layer an etch profile is formed and at least part of the etch profile includes a tapered profile such that openings at a bottom of the open mask have a first mask bottom dimension and a second mask bottom dimension wherein the first mask bottom dimension is larger than the second mask bottom dimension, and wherein at least one of: (a) the first mask bottom dimension is smaller than the first dimension, or (b) the second mask bottom dimension is smaller than the second dimension; and
etching the target layer through the patterned mask;
wherein during processing of the partially patterned mask with a hydrocarbon gas, a plasma deposition process is performed and further wherein during said plasma deposition process a direct current power is applied to the plasma.

19. A method according to claim 18, wherein during the plasma deposition, H2 and CₓH_{y}F_{z} are supplied at a flow rate ratio of H2 to CₓH_{y}F_{z} of from 4:1 to 10:1; and
wherein etching of the SiARC layer is performed in two steps at two different etch rates and two different plasma chemistries.

20. A method according to claim 18, wherein the direct current power is a negative voltage direct current power applied to an upper electrode during the plasma deposition, and wherein the negative voltage direct current power is not applied during etching of the SiARC layer; and
wherein etched features in the target layer have a first target layer dimension and a second target layer dimension, wherein the first target layer dimension is larger than the second target layer dimension, and wherein a first shrink amount is said first dimension minus said first target layer dimension, and a second shrink amount is said second dimension minus said second target layer dimension, and further wherein a ratio of said second shrink amount to said first shrink amount is 1:≦1; and
wherein the method further includes filling of the etched features of the target layer with a conductive metal.
